(19) United States
(12) Patent Application Publication
(10) Pub. No.: US 2025/0031347 A1
(43) Pub. Date: Jan. 23, 2025

(54) Three-Dimensional Meshes and Casings for Thermal Ground Planes

(71) Applicant: Kelvin Thermal Technologies, Inc., Boulder, CO (US)

(72) Inventors: Ryan Lewis, Boulder, CO (US); Jason West, Boulder, CO (US); Hunter Hach, Boulder, CO (US); Hagan Kolanz, Boulder, CO (US); Dylan McNally, Boulder, CO (US); Ben Hall, Boulder, CO (US); Keller Lofgren, Boulder, CO (US); Yung-Cheng Lee, Boulder, CO (US)

(21) Appl. No.: 18/779,455

(22) Filed: Jul. 22, 2024

Related U.S. Application Data
(60) Provisional application No. 63/515,013, filed on Jul. 21, 2023.

(51) Int. Cl. H05K 7/20; H05K 5/02

(52) U.S. Cl. CPC H05K 7/20336; H05K 5/0217; H05K 5/0247

(57) ABSTRACT

Three-dimensional meshes and three-dimensional casings for thermal ground planes are disclosed. These three-dimensional meshes and three-dimensional casings can create a vapor core that has structural resiliency positive or negative pressure differential between the vapor space and external conditions. A thermal ground plane is disclosed that includes a first casing that is substantially planar and a second casing. The outer periphery of the first casing and the outer periphery of the second casing are bonded together to form a hermetic seal. The second casing may be deformed to create a vapor support structure within the thermal ground plane that includes a plurality of deformed portions (or rough pillars). A working fluid may be disposed within the first casing and the second casing. Permeable wicks may also be disposed on an inner surface of the first casing and/or the second casing for liquid transport that is disposed between the first casing and the second casing.

### BACKGROUND

A thermal ground plane, also known as a vapor chamber, may provide a passive thermal management solution by enclosed microfluid systems. An advanced thermal ground plane may include a mesh wick permeated by some liquid. When heat is applied to the system, the liquid evaporates and generates a warm vapor within a vapor channel. The warm vapor has elevated pressure due to saturation pressure effect, and the elevated pressure causes internal convection currents in the vapor phase. That convection carries heat throughout the vapor phase, until the temperature is nearly uniform. The vapor condenses in cooler regions, and the condensed liquid is pulled back through the wick to the heat source by capillary forces resulting from the wick. A thermal ground plane, therefore, is able to spread heat. By using phase change and internal convection, a thermal ground plane can have effective conductivity much higher than solid heat spreaders such as copper or graphite.

### SUMMARY

Thermal ground planes are disclosed that can be used in various application such as, for example, space applications, mobile electronics, and high power electronics.

A thermal ground plane is disclosed that includes a first casing that is substantially planar and a second casing. The outer periphery of the first casing and the outer periphery of the second casing are bonded together to form a hermetic seal. The second casing may be deformed to create a vapor support structure within the thermal ground plane that includes a plurality of deformed portions (or rough pillars). A working fluid may be disposed within the first casing and the second casing. A permeable wick may also be disposed on an inner surface of the first casing for liquid transport that is disposed between the first casing and the second casing.

In one example of the thermal ground plane described above, the first casing and/or the second casing comprises at least one of copper, aluminum, and stainless steel. In one example of the thermal ground plane described above, the first casing and/or the second casing comprises a flexible laminate having a plurality of layers where at least one of the plurality of layers comprises polymer. The second casing, for example, has a thickness less than 0.036 mm.

In another example of the thermal ground plane described above, the permeable wick is bonded with both the first casing and portions of the second casing.

In one example of the thermal ground plane described above, the second wick disposed on an inner surface of the second casing. In another example, portions of the second wick can be bonded to the second casing and other portions of the second wick are bonded with the first wick. In yet another example, the permeable wick is flattened and deformed to form a plurality of deformations for liquid transport.

In one example of the thermal ground plane described above, the thermal ground plane may include a plurality of flexures that are configured to connect with a substrate and allow relative movement of portions of the thermal ground plane.

Another example thermal ground plane is disclosed. This thermal ground plan includes a first casing, and a first wick bonded with the first casing. The first wick can be useful for liquid transport associated with evaporation or boiling. This thermal ground plane may include a second casing, and a second wick bonded with the second casing. The second wick can be useful for liquid transport associated with condensation. The outer periphery of the first casing and the outer periphery of the second casing can be bonded to each other to form a hermetic seal. A liquid feed structure may be included that is in contact with the first wick and the second wick. The liquid feed structure may be useful for liquid transport. The liquid feed structure can have a structure configured to allow vertical liquid transport between the first wick and the second wick and horizontal liquid transport along the liquid feed structure. A working fluid can be disposed within the first casing and the second casing. The liquid feed structure, for example, may comprise a mesh selected from the group consisting of copper mesh, stainless teal mesh, and polymer mesh.

In one example of the thermal ground plane described above, the liquid feed structure may include a plurality of mesh layers.

As another example, the liquid feed structure can have a shape selected from the group consisting of a wavy shape, a triangular shape, a trapezoid shape, and an asymmetric wave shape.

In one example of the thermal ground plane described above, a vapor support structure disposed may be included between the first casing and the second casing. The vapor support structure and the liquid feed structure, for example, may be disposed in the space within the thermal ground plane.

In one example of the thermal ground plane described above, the second wick includes a plurality of mesh layers. The plurality of mesh layers, for example, may include at least a first mesh layer and a second mesh layer, the first mesh layer has a pore size greater than the pore size of the second mesh layer, and the first mesh layer is disposed between the second casing and the second mesh layer.

In one example of the thermal ground plane described above, the first wick includes a plurality of mesh layers. The plurality of mesh layers, for example, include at least a first mesh layer and a second mesh layer, the first mesh layer has a pore size greater than the pore size of the second mesh layer, and the second mesh layer is disposed between the first casing and the first mesh layer. The periphery of the plurality of mesh layers, for example, can be flattened for reduced pore size small enough to prevent vapor penetration into the liquid transport channel

### BRIEF DESCRIPTION OF THE FIGURES

FIG. 1A is a side view illustration of an internal structure of a thermal ground plane according to some embodiments.

FIG. 1B is an illustration of an example mesh.

FIG. 2A is an illustration of a side view of a thermal ground plane with a deformed top casing, a bottom casing, and a wick.

FIG. 2B is an illustration of a side view of the thermal ground plane with a top wick disposed on the inner surface of the top casing.

FIG. 3A is an illustration of a side view of a thermal ground plane with an internal bond between the top casing and the bottom casing.

FIG. 3B is an illustration of a side view of the thermal ground plane. In this example, the wick includes a wall formed in the wick perimeter.

FIG. 4A is an illustration of a side view of a thermal ground plane with a tiled wick and vapor support structure disposed within the top casing and a bottom casing.

FIG. 4B is an illustration of a side view of tiled mesh with each tile comprising a multilayer mesh with very small openings in the outer layer to prevent vapor penetrating into the fluid channel along the tiled meshes.

FIG. 4C is an illustration of a top view of the tiled mesh.

FIG. 5A is an illustration of a side view of a thermal ground plane with internal bonding between a deformed mesh for vapor transport and a wick. In this example, the top casing is substantially planar (e.g., not deformed).

FIG. 5B is an illustration of a side view of a thermal ground plane with a bottom deformed mesh for the wick including a flattened region as a wall to protect the liquid channel under the wick from vapor penetration.

FIG. 6 is an illustration of a side view of a thermal ground plane with portions of the vapor support structure cutaway or removed leaving openings in the mesh.

FIG. 7A illustrates a top view of a foldable thermal ground plane in a resting state.

FIG. 7B shows the foldable thermal ground plane in a stretched state.

FIG. 8A is an illustration of a side view of a thermal ground plane with a top condensation wick and a bottom evaporation/boiling wick connected by a liquid feed structure.

FIG. 8B is an illustration of a cut top view of a thermal ground plane with a plurality of liquid feed structures integrated with a plurality of vapor support structures.

FIG. 9A shows an example of a triangular liquid feed structure within a thermal ground plane.

FIG. 9B shows an example of an asymmetric wave shaped liquid feed structure within a thermal ground plane.

FIG. 10A illustrates an example of a deformed mesh for a condensation wick.

FIG. 10B illustrates an example of a multilayer mesh for a condensation wick.

FIG. 11 illustrates an example of a multilayer mesh for an evaporation/boiling wick.

FIG. 12 is an illustration of a side view of a thermal ground plane that includes two types of vapor support structures.

FIG. 13 is an illustration of a side view of a thermal ground plane that includes a deformed mesh that serves as a liquid feed and a vapor support structures.

### DETAILED DESCRIPTION

Three-dimensional meshes and casings for advanced thermal ground planes, among other things, are disclosed. A thermal ground plane, also known as a vapor chamber, is a passive thermal management solution with enclosed microfluid systems. A thermal ground plane typically includes a wick permeated by some liquid. When heat is applied to the system, the liquid evaporates and generates a warm vapor within a vapor cavity. The warm vapor has elevated pressure due to saturation pressure effect, which causes internal convection currents in the vapor phase. This convection carries heat throughout the vapor phase, until the temperature is nearly uniform. The vapor condenses in cooler regions, and the condensed liquid is pulled back through the wick to the heat source by capillary forces resulting from the wick. A thermal ground plane, therefore, may be able to spread heat. By using phase change and internal convection, a thermal ground plane can have effective conductivity much higher than solid heat spreaders such as copper or graphite.

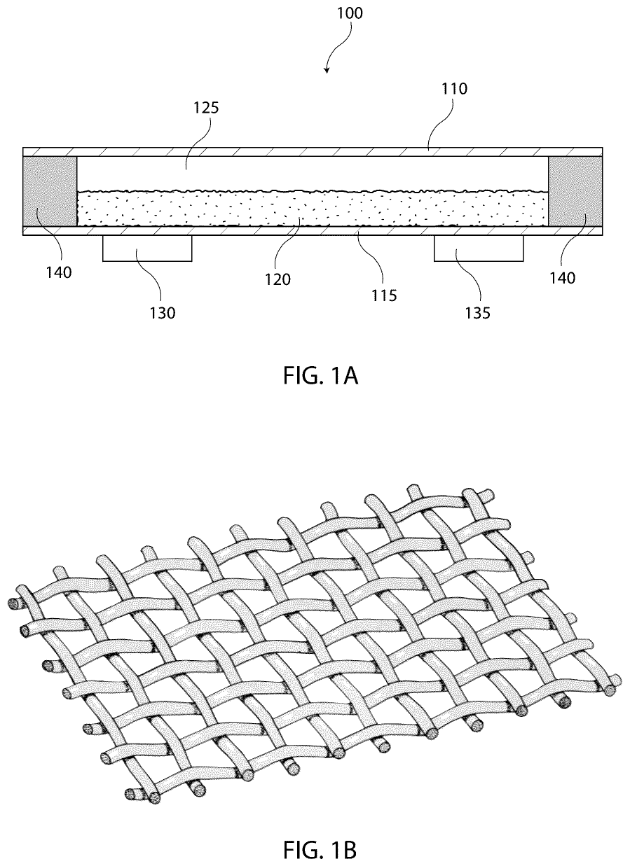

The elements of a thermal ground plane are the outer casing, wick structure, vapor space, and encapsulated fluid, as in FIG. 1. Meshes are used as wicks in most of thermal ground planes. To meet challenging requirements of new applications of thermal ground planes, improvements to the meshes and casings can be useful. A major improvement is to apply three-dimensional configurations that can offer the features well beyond what two-dimensional can achieve.

The examples of thermal ground planes described in this document and shown in any of the figures are not drawn to scale and features may be out of proportion relative to other features. Some features shown in the figures may be exaggerated for illustration purposes.

FIG. 1A is a diagram of a thermal ground plane 100 according to some embodiments. In this example, the thermal ground plane 100 includes a top casing 110, a bottom casing 115, a wick 120 (or liquid structure), and/or a vapor structure 125. The thermal ground plane 100, for example, may operate with evaporation, vapor transport, condensation, and liquid return of water or other cooling media for heat transfer between the evaporation region 130 and the condensation region 135. The structures and/or characteristics of the thermal ground plane 100 may be applied to any embodiment or example described within this document.

The top casing 110, for example, may include copper, stainless steel, aluminum, polymer, atomic layer deposition (ALD) coated polymer, flexible copper clad laminate (FCCL), polymer-coated copper, copper-cladded Kapton, etc. The bottom casing 115, for example, may include copper, stainless steel, aluminum, polymer, ALD coated polymer, FCCL, polymer-coated copper, copper-cladded Kapton, etc. The top casing 110 and the bottom casing 115, for example, may be sealed together using solder, laser welding, ultrasonic welding, electrostatic welding, or thermocompression bonding (e.g., diffusion bonding) or a sealant. The top casing 110 and the bottom casing 115, for example, may include the same or different materials.

The top casing 110 and/or the bottom casing 115, for example, may comprise a flexible copper clad laminate with at least three layers: a first layer of copper (e.g., 12 microns thick), a second layer of polyimide (e.g., 12 microns thick), and a third layer of copper (e.g., 12 microns thick). Each of these three layers may have a thickness of or less than 50, 20, 15, 12, 10, 8 microns. The polyimide, for example, may be sandwiched between two copper layers. The copper layers on the top casing and/or the bottom casing, for example, can be replaced with ALD nano-scaled layers such as, for example, Al₂O₃, TiO₂, SiO₂, for extremely thin casings (e.g., with a thickness less than about 10 microns).

The evaporation region 130 and the condensation region 135 may both be disposed on the top casing 110 or on the bottom casing 115. Alternatively, the evaporation region 130 and the condensation region 135 may be disposed on different layers of the top casing 110 and the bottom casing 115.

In some embodiments, the vapor structure 125 may be formed from the top casing 110 that has been deformed into various geometric shapes that may improve reliability of structure under pressure difference between the vapor pressure inside the thermal ground plane and the ambient pressure outside the thermal ground plane during folding and unfolding, thermal transport, the flow permeability, the capillary radius, the effective thermal conductivity, the effective heat transfer coefficient of evaporation, and/or the effective heat transfer coefficient of condensation. In some embodiments, the initial structure may include multiple layers of mesh.

In some embodiments, the outer periphery of the top casing 110 and the outer periphery of the bottom casing 115 may be sealed at perimeter bond 140 such as, for example, hermetically sealed using any number of techniques.

Various examples described in this disclosure include a mesh. FIG. 1B is an example of a mesh that is woven. The term mesh as used throughout this disclosure may, in some examples, include a mesh with a structure similar to what shown in FIG. 1B where a plurality of threads are woven together to create material with a plurality of pores. Various other types of mesh may also be used.

A mesh, for example, may comprise copper and/or stainless steel. A mesh, for example, may include a material having pores that have a dimension of about 10 to 200 μm. A nonporous mesh, for example, may include a material that may have pores that a have a dimension of about 0.2 to 10 μm. A mesh may be characterized by a pore size and/or a mesh number. The pore size indicates the average size of the pores within the mesh. For example, the average pore size of the pores in a mesh may be 0.05 mm. The mesh number indicates the average number of threads or openings per inch. For example, a mesh with a mesh number #400 has 400 threads or openings per inch.

A mesh, for example, may include a material that includes either or both metal and polymer. A deformed wavy mesh, for example, may be highly stretchable, such as, for example, stretchable without plastic deformation, which may, for example, reduce the stress when folded and/or may prevent the formation of wrinkles and blocking of vapor flow. A mesh, for example, may be electrically conductive and/or may be coated in a dielectric material such as, for example, to prevent plating of material into the pores away from the anchors. The pores in a mesh, for example, may be made from polymer, ceramic, other electrically insulating materials or electrically conductive material and/or may be covered by an electrically insulating layer. A mesh, for example, may include woven wires, non-woven wires, or porous planar media. A mesh, for example, may include an ALD-coated polymer without any metal. The ALD coating can be replaced with other thin film coatings. A mesh, for example, may include a copper-clad-polyimide laminate material. A mesh, for example, may include a copper mesh or non-copper mesh such as, for example, a polymer mesh or a stainless steel mesh. The mesh, for example, may be encapsulated by hydrophilic and anti-corrosion hermetic seal. A mesh, for example, may include any woven or nonwoven material.

A mesh, for example, may have a thickness of about 10 μm to about 1,000 μm. A woven mesh, for example, may have a thickness of about 1,000, 500, 125, 100, 75, 50, or 25 μm. A porous mesh (e.g., a nanoporous mesh and/or a non-woven mesh) may have a thickness of about 5, 10, 15, 20, or 25 μm. A mesh, for example, may include a metal foam.

Various thermal ground planes described in this disclosure may include an array of pillars, which may include any or all of the following. An array of pillars, for example, may include a plurality of pillars with an evenly or unevenly distributed pattern. An array of pillars, for example, may include pillars comprising polymer. An array of pillars, for example, may include pillars comprising metal such as, for example, copper or stainless steel. An array of pillars, for example, may include pillars coated with a coating such as, for example, a ceramic (e.g. Al₂O₃, TiO₂, SiO₂, etc.) or a nano-texture coating. The coating may be applied via defect-free ALD, low-defect density ALD, chemical vapor deposition (CVD), molecular layer deposition (MLD), or other nano-scaled or micro-scaled coating processes.

An array of pillars, for example, may be a pseudo-rectangular array, or a pseudo hexagonal array, or a random array. An array of pillars, for example, may have a center-to-center pitch that is constant across array of pillars. An array of pillars, for example, may include pillars with variable diameters and/or heights. An array of pillars, for example, may have a low density (e.g., far apart) at the condenser, have a higher density at the evaporator, and/or gradual change in density between the condenser and the evaporator.

Various examples described in this disclosure include a micro pillar array. For example, a micro pillar array may be disposed on an array of pillars, where the array of pillars are larger than the micro pillar array. A micro pillar array, for example, may include a deformed mesh or a porous material in which the pore size of the material is substantially smaller than the gap between pillars. A micro pillar array may, for example, include nano-wire bundles, sintered particles, templated grown pillars, inverse opals, etc. A micro pillar, for example, array may include solid pillars, which may promote conduction of heat along the length, and outer regions of the micropillar array may be porous to promote wicking.

Various examples described in this disclosure may include internal thermal ground plane structures comprising polymer. These thermal ground plane structures, for example, may include the top casing, the bottom casing, a mesh, an array of pillars, arteries, wick, vapor structures, etc. Polymer structures, for example, may be coated with metal, defect-free ALD, low-defect density ALD, CVD, MLD, or other nano-scaled coating processes.

Thermal ground planes disclosed in this document may be used for any number of applications such as, for example, for space systems. For space systems, for example, a thermal ground plane may be designed for ultra-light weight with high performance, where there is a positive or negative pressure differential between the vapor space and external conditions.

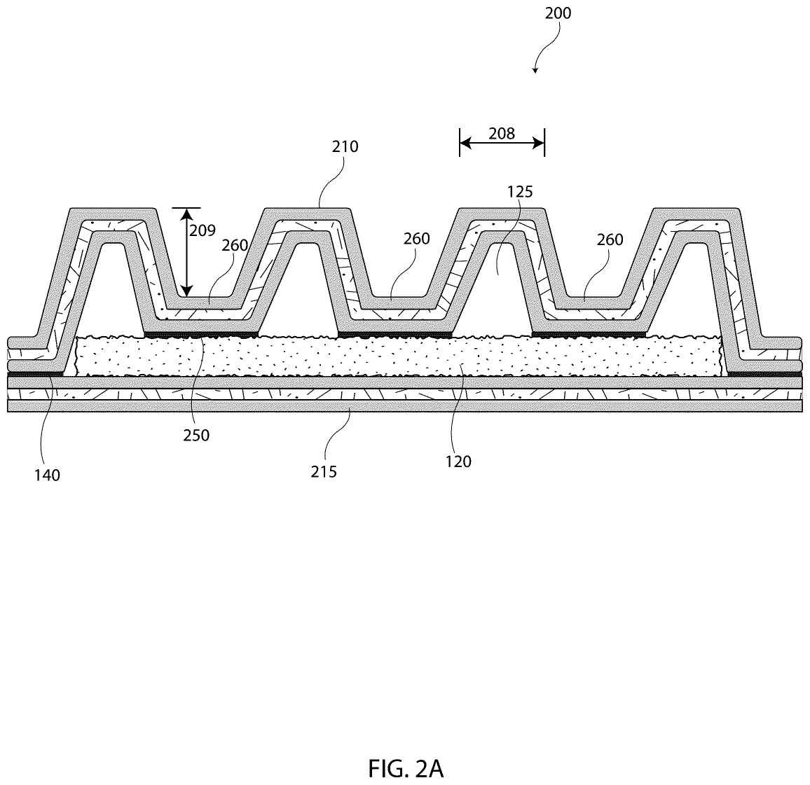

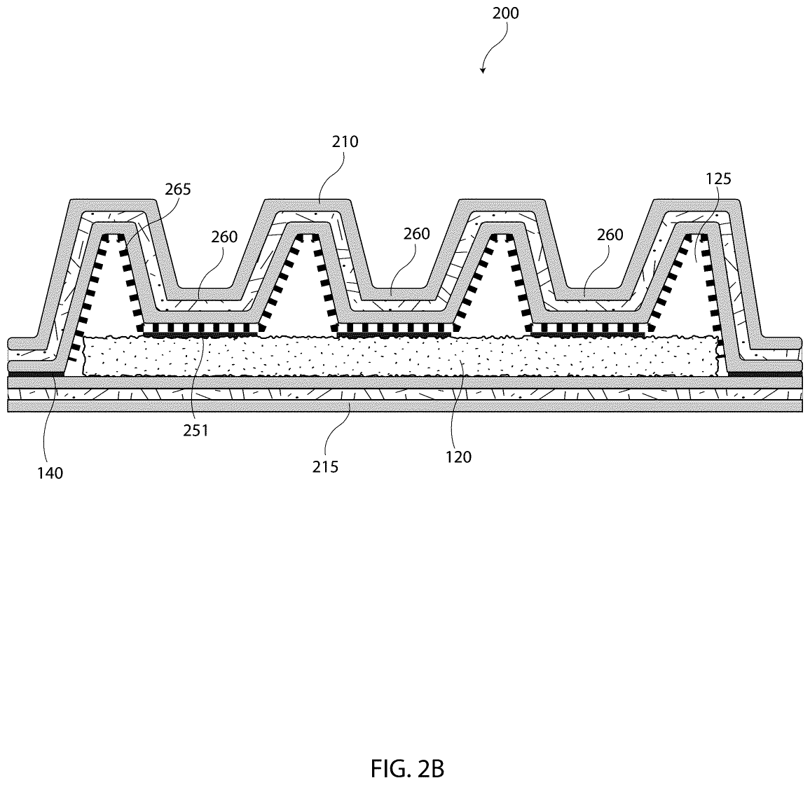

FIG. 2A is an illustration of a side view of a thermal ground plane 200 with a deformed top casing 210, a bottom casing 215, and a wick 120. The top casing 210 and the bottom casing 215 may enclose the wick 120 and may be sealed at the perimeter bond 140 on the periphery of the top casing 210 and the bottom casing 215. The top casing 210 and the bottom casing 215 may include any number of layers. In this example, three layers are shown and may include a laminate of copper, polyimide, and copper. Various other layers may be included in the top casing 210 and/or the bottom casing 215.

The top casing 210 and/or the bottom casing 215, for example, may include one or more layers of copper, aluminum, stainless steel, or other metal materials. The top casing 210 and/or the bottom casing 215, for example, may include one or more layers of copper, stainless steel, aluminum, polymer, ALD coated polymer, FCCL, polymer-coated copper, copper-cladded Kapton, etc. The thickness of the top casing 210 and/or the thickness of the bottom casing 215, for example, may be less than about 0.01 mm, 0.024 mm, 0.036 mm, 0.050 mm, 0.075 mm, 0.1 mm, 0.2 mm, 1 mm, 2 mm, etc.

The top casing 210 may be deformed to include a plurality of deformed portions 260 (or casing pillars or rough pillars) formed into a top casing 210. With deformed portions 260 in the top casing 210, the top casing 210 may be considered a 3D casing. The plurality of deformed portions 260 may provide structural integrity within the thermal ground plane. The deformed portions 260, for example, may be deformations formed into a planar casing. The plurality of deformed portions 260 may extend into the vapor structure 125 of the thermal ground plane 200. The plurality of deformed structures, for example, may be randomly formed across the top casing 210. he plurality of deformed structures, for example, may be formed in an ordered array in the top casing 210. The width 208 (or average width) between deformed portions 260, for example, may be less than 0.1 mm, 0.3 mm, 0.5 mm, 0.75 mm, 1 mm, 2 mm, 4 mm, etc. The depth 209 (or average depth) of the plurality of deformed portions 260, for example, may be less than about 500 microns, 200 microns, 100 microns, 50 microns, 25 microns, etc.

The top casing 210, for example, may be formed from a planar sheet to include the plurality of deformed portions 260. The plurality of deformed portions 260 may be deformations that extend out of plane relative the planar sheet.

An internal surface of the plurality of deformed portions 260 may be bonded 250 with a top surface of the wick 120. The wick 120 may be bonded with the bottom casing 215, for example, to maintain structure integrity under pressure difference between the vapor pressure inside the thermal ground plane and ambient pressure outside the thermal ground plane. This may, for example, create internal bonding and/or may provide support to allow for a high internal pressure. One or more of the plurality of deformed portions 260, for example, may be bonded with corresponding portions of the wick 120 that are also deformed in some manner.

One or more of the plurality of deformed portions 260, for example, may be bonded on top of the wick 120 or pressed or formed into the wick 120 at bond interface 250, for example, to maintain structure integrity under pressure difference between the vapor pressure inside the thermal ground plane and ambient pressure outside the thermal ground plane. As another example, the wick 120 may include a plurality of pillars and one or more of the plurality of deformed portions 260 may be bonded on top of the wick 120 or into the wick 120. The wick 120, for example, may include a copper mesh.

As another example, the bond interface 250 may not be included. In this example, no internal bonding may be required. For example, one or more of the plurality of deformed portions 260 may be in contact the wick 120 without a bond interface 250. As another example, one or more of the plurality of deformed portions 260 may not be in contact the wick 120.

The wick 120, for example, may include a woven mesh, non-woven mesh, deformed mesh, mesh-on-pillars, a plurality of pillars, a plurality of micropillars, etc. The wick 120, for example, may comprise copper, aluminum, stainless steel, FCCL, polymers, polymer and metal combinations, organic material, inorganic material, etc.

The wick 120 may be bonded with the bottom casing 215, for example, to maintain structure integrity under pressure difference between the vapor pressure inside the thermal ground plane and ambient pressure outside the thermal ground plane. The wick 120 may be bonded with portions of the plurality of deformed portions 260 at bond interface 250, for example, to maintain structure integrity under pressure difference between the vapor pressure inside the thermal ground plane and ambient pressure outside the thermal ground plane.

FIG. 2B is an illustration of a side view of the thermal ground plane 200 with a top wick 265 disposed on the inner surface of the top casing 210. The top wick 265 and the wick 120 may be bonded together at bond interface 251. The bond interface 251 may be located on a portion of the top wick 265 corresponding to one or more of the plurality of deformed portions 260.

The top wick 265 may be bonded with the inner surface of the top casing 210 prior to forming the plurality of deformed portions 260.

The top wick 265 and/or the wick 120, for example, may be formed by bonding multiple layers of mesh to create a multilayer wick.

In the case of deformed mesh or mesh-on-pillars, the mesh may be flattened along the perimeter to form a wall with low capillary radius. Or the mesh can be bonded in the bondline that hermetically seal the thermal ground plane. The mesh bonded in the bondline forms a solid wall. A wall can prevent vapor from penetrating to the porous wick or the liquid channel below the wick. The vapor bubbles can block fluid flow in the liquid channel and reduce the maximum power allowable for a thermal ground plane.

The wick 120, for example, may comprise a plurality of layers of mesh bonded together. Some of the plurality of layers may have different mesh numbers such that a finer mesh may be disposed at the vapor/liquid interface to provide capillary force and a coarser mesh further away from the vapor/liquid interface to allow high permeability flow.

The wick 120, for example, can be a deformed mesh with mesh pillars formed during a deformation process.

As another example, the top casing 210 may be bonded with a vapor support structure that includes a polymer over the top casing 210 filling the deformed cavity outside the thermal ground plane. The polymer may be fluorinated ethylene propylene (FEP) and provide a high infrared emissivity.

The wick 120 may be bonded with the bottom casing 215, for example, to maintain structure integrity under pressure difference between the vapor pressure inside the thermal ground plane and ambient pressure outside the thermal ground plane. The top wick 265 may be bonded with the top casing 210, for example, to maintain structure integrity under pressure difference between the vapor pressure inside the thermal ground plane and ambient pressure outside the thermal ground plane. The wick 120 may be bonded with portions of the top wick 265 at bond interface 251, for example, to maintain structure integrity under pressure difference between the vapor pressure inside the thermal ground plane and ambient pressure outside the thermal ground plane.

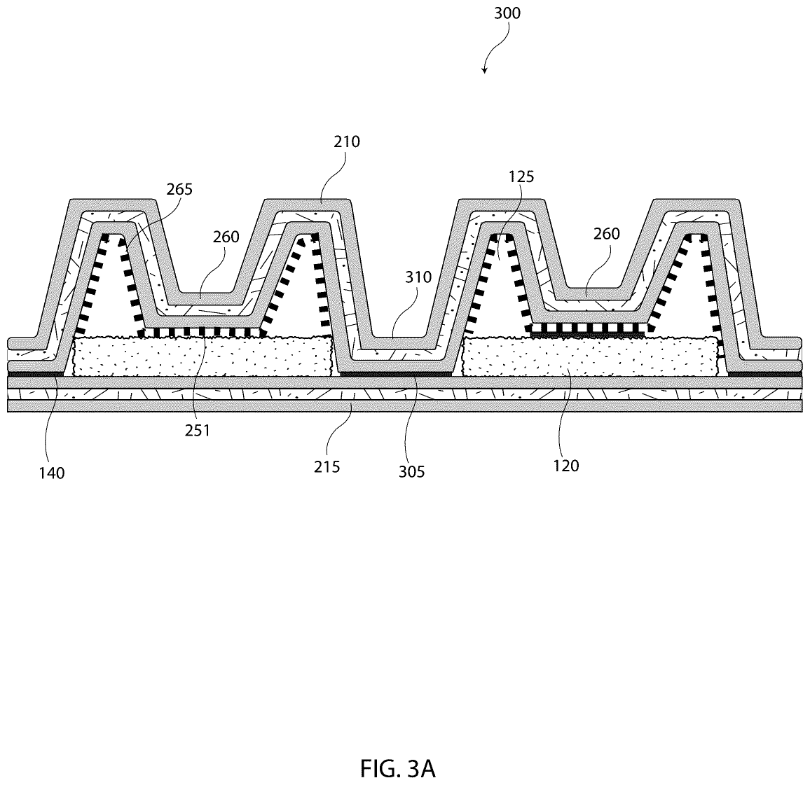

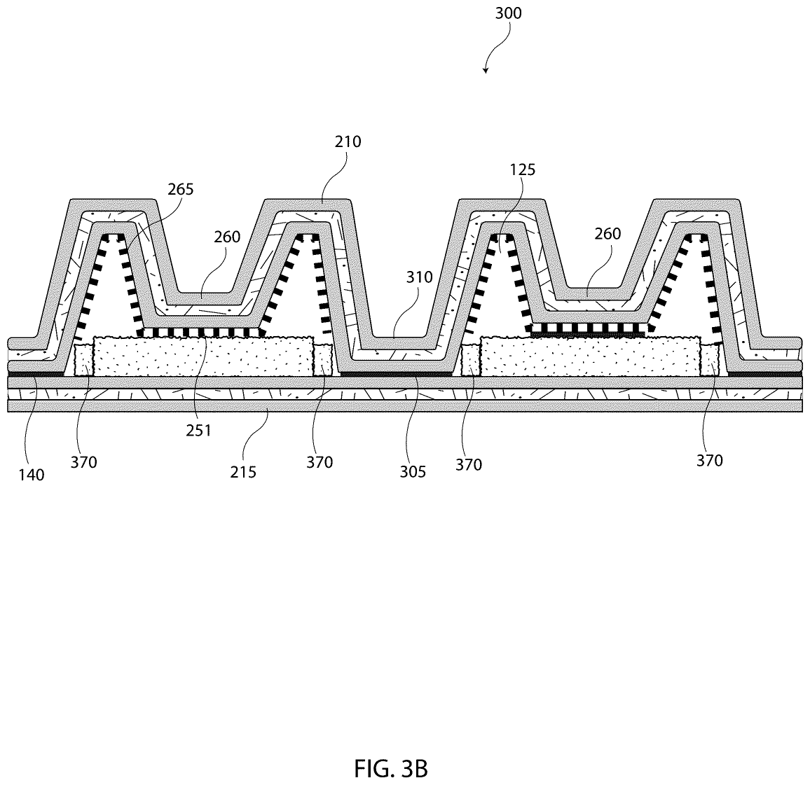

FIG. 3A is an illustration of a side view of a thermal ground plane 300 with an internal bonding 305 between the top casing 210 and the bottom casing 215. The thermal ground plane 300 is similar to the thermal ground plane 200. The internal bonding 305 may be formed by an elongated deformed portion 310. At the internal bonding 305, the thickness of the thermal ground plane at the internal bond is substantially identical to the thickness at the perimeter bond 140. A diffusion bonding process, for example, using a flat tool, may be used to further deform the top casing 210 to form the internal bonding 305. The wick 120, for example, may have a hole to allow the elongated deformed portion 310 to pass through the wick 120 and bond with the bottom casing 215. The top wick 265, for example, may have a hole that allows the elongated deformed portion 310 to pass through the top wick 265 and bond with the bottom casing 215.

A plurality of elongated deformed portions 310 may be included.

The top casing 210 and the bottom casing 215 may be bonded to a wick structure and these wick structures may have holes to allow the top casing 210 and the bottom casing 215 to touch and be bonded together. The bonding of the top casing 210 with the bottom casing 215, can be done, for example, to maintain structure integrity under pressure difference between the vapor pressure inside the thermal ground plane and ambient pressure outside the thermal ground plane.

FIG. 3B is an illustration of a side view of the thermal ground plane 300. In this example, the wick 120 includes a wick perimeter 370. The wick perimeter 370 may surround the wick 120 and/or any holes in the wick 120. The wick perimeter 370 may include the same material as the wick 120 that is compressed to form smaller pores in the wick perimeter 370. The smaller pores can protect the liquid channel under the wick from vapor penetration.

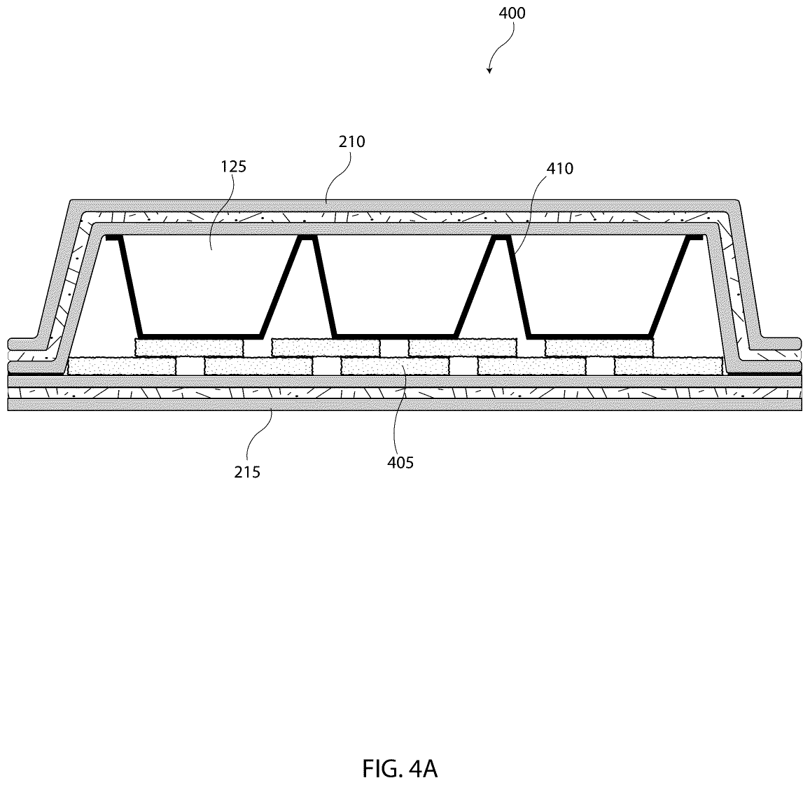

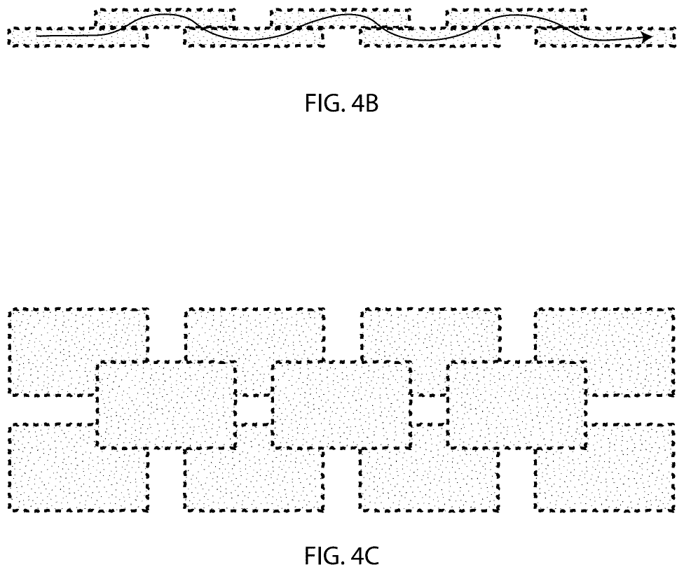

FIG. 4A is an illustration of a side view of a thermal ground plane 400 with a tiled wick 405 and vapor support structure 410 disposed within the top casing 210 and a bottom casing 215. The tiled wick 405, for example, may include a plurality of tiles of wick in multiple layers. The tiled wick 405 and the vapor support structure 410 may or may not be bonded together.

The individual tiles of the tiled wick 405 may include two layers of deformed mesh: one of which is deformed into a substantially flat side and the other into a substantially pillar-side. The two mesh layers can be bonded together along the pillars as well as along the perimeter. This can create a high permeability flow channel between the mesh layers, while forcing a low capillary radius at any vapor-liquid interface. An alternative method to reach both high permeability and low capillary radius may include a fine mesh that encapsulates a coarse mesh on the top and the bottom.

Multiple tiles of wick, for example, can be stacked in an overlapping pattern as shown in FIG. 4B and FIG. 4C. The interface between two tiles, for example, may have a low permeability and/or a low capillary radius. Liquid may flow through the area of low permeability over a wide area, which may allow the liquid to flow with a small flow resistance. A large single wick structure such as a mesh layer, for example, can be placed below all of the tiles, where the single mesh has a capillary radius which is similar to or smaller than the capillary radius of the tiles. In such a way, liquid can flow through the tile or the mesh while maintaining surface tension associated with the small capillary radius.

The vapor support structure 410, for example, may include a foil bent to form a plurality of pillars. The vapor support structure 410 may be separate and distinct from the top casing 210 and/or the bottom casing 215. The vapor support structure 410 can include FCCL, metal, copper mesh, and/or can be porous or solid. In some examples, the vapor support structure 410 can include multiple foils which are not bonded together. The foil may be corrugated in regions without deformed vapor pillars formed by a deformed mesh, to increase the stiffness of the top casing 210 and/or the bottom casing 215. The top casing 210, for example, may be deformed to provide the deformed vapor pillars with corrugated structure.

The wick of each tile, for example, may include a deformed mesh with a substantially flat side facing the vapor-liquid interface and a substantially pillar-shaped side facing the liquid region. The perimeter of the deformed mesh can be substantially flattened to create a wall region of low capillary radius. Selective regions of the wick are compressed to extend the height of the vapor cavity.

Selective regions of the wick of the tile, for example, may be cut away to create extended vapor flow cavities, which may be referred to a deformed-open mesh (DO-Mesh). Multiple strings of vapor flow cut-outs in the mesh may be lined up in an alternating layout, to allow parallel paths of vapor flow. In some examples, the selective regions cut out of the wick may have the perimeter partially filled to form a wall region with low capillary radius. The wall regions can be formed by flattening a mesh to include a flattened area on the periphery of the mesh, or the wall regions can be formed by the process of cutting the opening region such as by laser cutting with melt regions forming the wall.

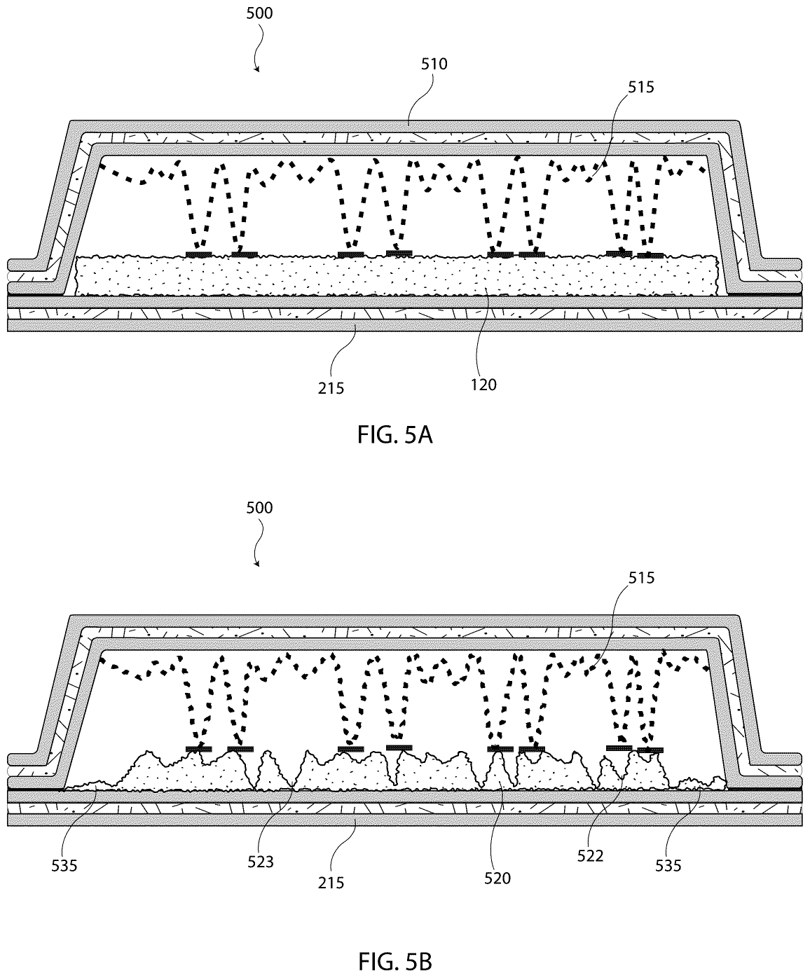

FIG. 5A is an illustration of a side view of a thermal ground plane 500 with internal bonding. In this example, the top casing 510 is substantially planar (e.g., not deformed). The top casing 510 and the bottom casing 215 may be sealed around the periphery of the top casing 510 and the periphery of the bottom casing 215. The vapor support structure 515 and wick 120 may be disposed within the thermal ground plane 500. In one example, the vapor support structure 515 may be bonded with the top casing 510. In another example, the vapor support structure 515 may be bonded with the wick 120 that is bonded with bottom casing 215. In another example, the vapor support structure 515 may be bonded with both the top casing 510 and the wick 120. The wick 120 can be bonded to bottom casing 215.

The vapor support structure 515, for example, may include any of the features and/or characteristics of the vapor support structure 410. The vapor support structure 515, for example, may include the same material or substantially the same material as the wick 120. For example, the wick 120 may comprise a layer or layers of mesh with a first mesh number and the vapor support structure 515 may comprise layers of mesh with a second mesh number that is lower than the first mesh number. In one specific example, the wick 120 may have a mesh number of about #250 and the vapor support structure 515 may have a mesh number of about #80. As another example, the wick 120 may comprise a plurality of layers of mesh with different mesh numbers and the vapor support structure 515 may have a mesh number that is less than the average of the mesh numbers of the plurality of layers of mesh.

The vapor support structure 515 may be bonded with the top casing 510, for example, to maintain structure integrity under pressure difference between the vapor pressure inside the thermal ground plane and ambient pressure outside the thermal ground plane. The wick 120 may be bonded with the vapor support structure 515, for example, to maintain structure integrity under pressure difference between the vapor pressure inside the thermal ground plane and ambient pressure outside the thermal ground plane. The wick 120 may be bonded with the bottom casing 215, for example, to maintain structure integrity under pressure difference between the vapor pressure inside the thermal ground plane and ambient pressure outside the thermal ground plane.

FIG. 5B is an illustration of a side view of a thermal ground plane 500 with the wick 120 replaced with deformed wick 520. The deformed wick 520 may be one or more layers of mesh that are deformed to include a plurality of deformations. One or more of the plurality of deformations, for example, may extend more than substantially halfway through the wick in a vertical direction (first deformation 522) and/or one or more of the plurality of deformations may extend substantially all the way through the wick in a vertical direction (second deformation 523). These deformations may be created by pressure flattening portions of the deformed wick 520.

The deformed wick 520, for example, may be flattened around the perimeter 535. The flattened perimeter 535 may create areas with smaller pore sizes, which creates areas which limit vapor flow into the deformed wick 520. The vapor support structure 515 may include a mesh with a lower mesh number than the mesh number of the deformed wick 520.

As another example, the deformed wick 520 may be flattened and deformed around all or substantially all the volume of the deformed wick 520. This may create smaller pore sizes for the entire deformed wick 520. For example, a mesh may first be flattened around the entire body of the mesh. This may create smaller pore sizes throughout the body of the mesh. The flattened mesh may then be deformed to create various deformations (e.g., first deformation 522 and/or second deformation 523) in portions of the mesh such as, for example, at the periphery or other regions of the deformed wick 520. For example, a mesh with a pore size of #200 can be flattened, which changes the pore size of the mesh to about #600.

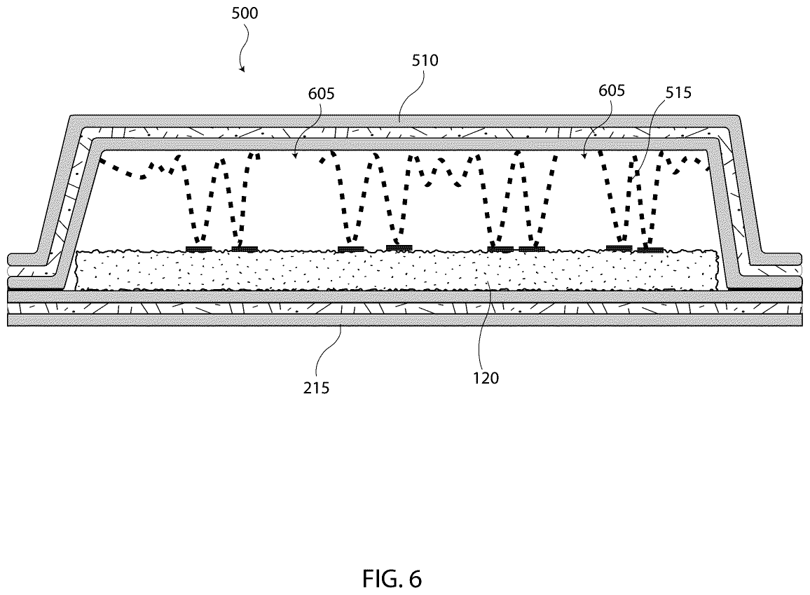

FIG. 6 is an illustration of a side view of a thermal ground plane 500 with portions of the vapor support structure 515 cutaway or removed leaving openings 605 in the deformed-open mesh (DO-mesh). The regions of the vapor support structure 515 that remain can provide mechanical support to the top casing 510. The openings 605 in the vapor support structure 515 can be aligned with the wick 120, which can also be a deformed wick 520 as shown in FIG. 5B. In some embodiments, the vapor support structure 515 may include cross-connectors of mesh within the openings 605, which may provide mechanical robustness to the openings 605. The cross-connectors, for example, may mis-align between the vapor support structure 515 and the wick 120 or the deformed wick 520, preventing any bottleneck in the vapor flow region.

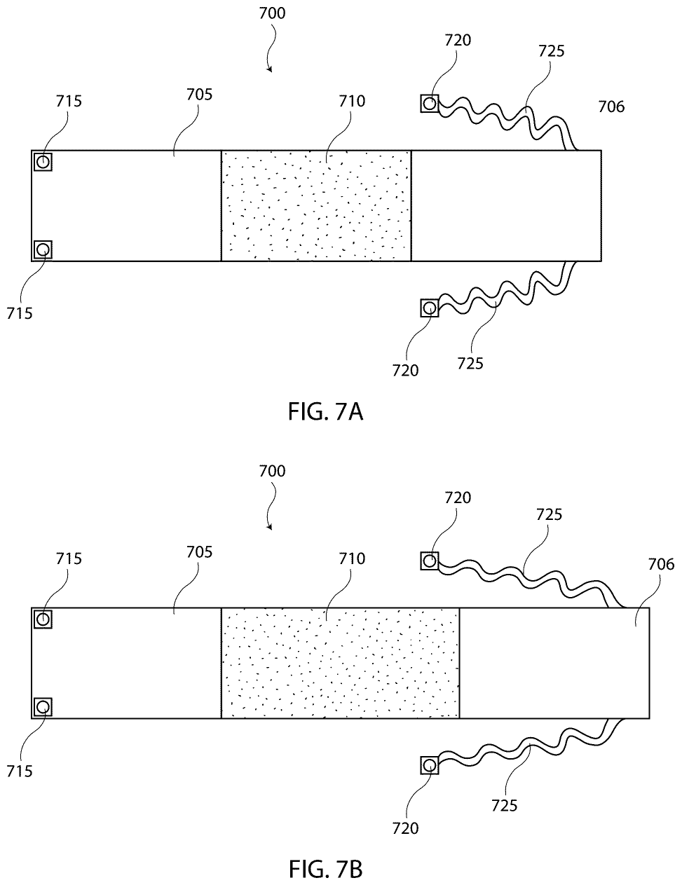

FIG. 7A illustrates a top view of a foldable thermal ground plane 700 in a resting state and FIG. 7B shows the foldable thermal ground plane 700 in a stretched state. The foldable thermal ground plane 700 may be used, for example, in folding mobile devices. As the mobile device folds the foldable thermal ground plane 700 may stretch and extend. The foldable thermal ground plane 700 may allow for stretching and extending without damage.

Foldable thermal ground plane 700 has a first stiff region 705 and a second stiff region 706 and a foldable region 710. The foldable region 710 may be disposed between the first stiff region 705 and the second stiff region 706. The first stiff region 705 may have one or more attachment points 715 that allow the first stiff region 705 to be secured directly to an electrical device. The second stiff region 706 may include one or more flexures 725 that extend from the second stiff region 706 to an attachment point 720. The attachment point 720 and/or the one or more attachment points 715 may be configured to be secured with heating region in use.

In use, as the foldable region 710 bends the second stiff region 706 may move relative to the electrical device without damaging the attachment points 720 as the one or more flexures 725 stretch and return during folding actions. The foldable region 710 and/or the second stiff region 706 may slide relative to the electrical device. The use of the one or more flexures 725 may allow relative movements of all or portions of the foldable thermal ground plane 700 to move in the horizontal directions with very limited movements in the vertical direction.

A thermal connection may be included to thermally connect the foldable thermal ground plane 700 with an electrical device. The thermal connection may include an air gap, a low-friction thermal interface that allows the thermal ground plane to slip across the surface (e.g., polytetrafluoroethane or graphite), or through a stretchable elastomeric material.

The foldable thermal ground plane 700 may include waves in the top casing and the bottom casing which may not be bonded to a wick. The wick may include cut-out regions for vapor to flow in a side-by-side configuration with the liquid in the wick. The wick may be substantially flat between the waves in the casing. The wick, for example, may be substantially wavy with the same wavelength as the waves in the casing. The top casing material and the bottom casing material can be asymmetric. The waves in the top casing and the bottom casing may extend to and include the bonding region between the upper and lower casing. A wavy bond-line necessitates that the top casing and the bottom casing be able to nest within each other. These waves may include sinewaves, circular waves, elliptical waves, and rounded triangular waves. The wave shape, for example, may not be nestable because of asymmetry in the wave shape. Such asymmetric waves can reduce the strain associated with both forming waves and with bending the wavy region. The foldable thermal ground plane 700 may have waves which transition from one wavy design above the wick to a different wavy design in the bonding region. The thermal ground plane 700 may also include one wavy design above the wick which transitions to a flat region over the bonding region. The shape of the transition may follow a smooth curve with two or more inflection points.

The wick and vapor space of the foldable thermal ground plane 700 may be formed in different ways. The wick in the first stiff region 705 and the second stiff region 706 may be defined by a high-capillary-pressure type wick, while the wick in the foldable region 710 can be defined by a multi-layer mesh where the mesh layers are bonded together. The high-capillary-pressure wick, for example, can be formed by a mesh-on-pillars architecture. The pillars, for example, can form a solid wall around the perimeter of the high-capillary-pressure wick, which may prevent a vapor ingress into the wick under the mesh. The wall, for example, can be porous with a substantially smaller pore size than the pore size of the wick. The mesh/pillar architecture, for example, can be formed by a single deformed mesh as shown in FIG. 5B. The transition from the wavy-region mesh to the flat-region mesh can include a multi-layer mesh extending substantially into the flat region. In this region, the multi-layer mesh, for example, may be deformed to create vapor-support pillars. The multi-layer mesh, for example, can be cut to form a plurality of vapor flow channels in addition to the vapor cavity formed by the support structures.

The foldable thermal ground plane 700, for example, can include a micro/nano-porous membrane in the foldable region 710. A layer of micro/nano-porous membranes can be bonded to a pillar array, in first stiff region first stiff region 705, second stiff region 706, and/or foldable region 710. Such a layer of micro/nano-porous membranes can sustain high capillary pressure even with fluids with low surface tension, including alcohols such as methanol, ethanol, and isopropanol; organic solvents such as acetone, pentane, and isohexane; and engineered fluids such as hydrofluoroethers, hydrofluoroketones, and other dielectric fluids. In such folding regions, the vapor flow channel is formed by gaps in the wick. The layer of micro/nano-porous membranes with a solid wall can be formed between the pillars' area and the vapor flow, to prevent vapor ingress under the membrane. The bottom of the pillar array may be solid or porous, and if porous it may be bonded to a second micro/nano-porous material. The material for the micro/nano-porous membrane may be polymer such as polyimide, polyester, polycarbonate, PEEK, etc.; metal such as steel, stainless steel, aluminum, copper, brass, etc.; or flexible ceramic such as glass, aluminum oxide, etc. The micro/nano-scale pores may be formed by mesh flattening, track-etching, dealloying, co-polymer formation, photolithography and etching or electroforming, anodizing, etc.

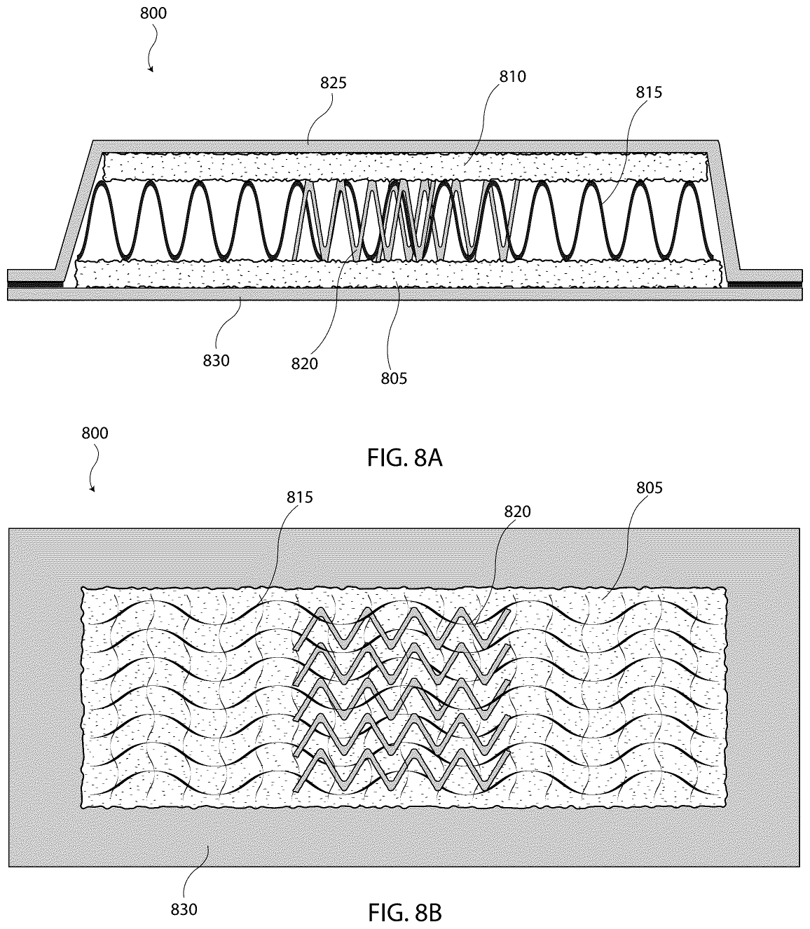

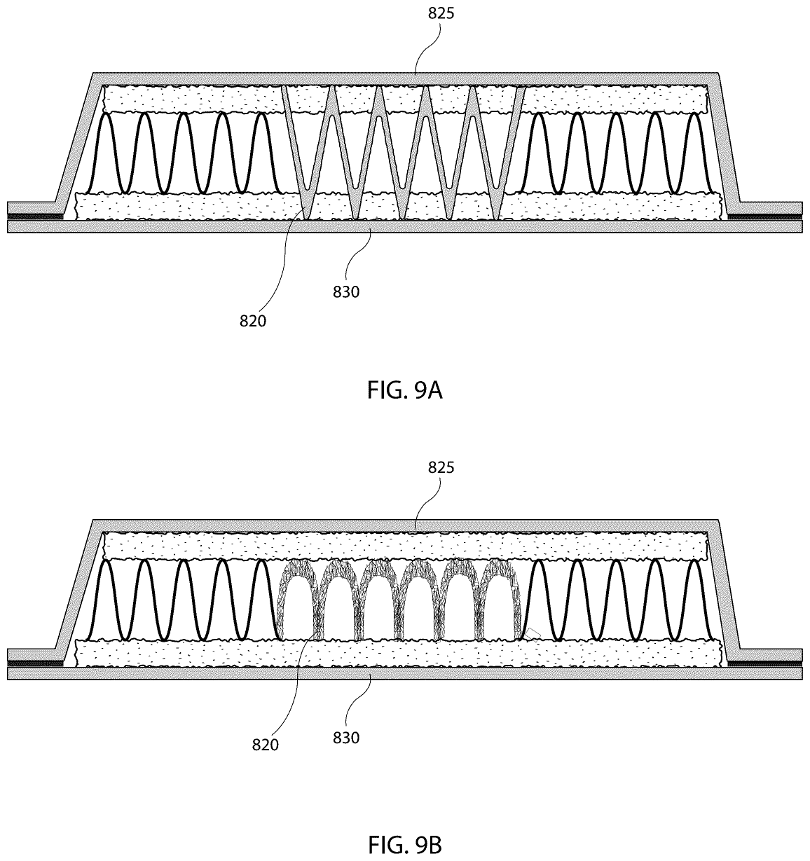

The thermal ground planes shown in FIG. 8A-FIG. 13 can be used for any application such as, for example, high power and high heat flux applications. High power applications may include cooling processors (e.g., AI processors, graphics processors, etc.), high power switches (e.g., MOSFETs, GaN, etc.), etc.

FIG. 8A is an illustration of a side view and FIG. 8B is an illustration of a cut top view of a thermal ground plane 800 that may, for example, be used in high power and high heat flux applications. In this example, the bottom casing 830 is substantially planar (e.g., not deformed) and flat. The top casing 825 and the bottom casing 830 may be sealed around the periphery of the top casing 825 and the periphery of the bottom casing 830.

The top casing 825, for example, may include a single layer of material that has high thermal conductivity. The top casing 825, for example, may comprise copper, aluminum, stainless steel, silicon, ceramic, AlN, BeO, etc. The top casing 825, for example, may include a material that has a thermal conductivity greater than about 200 W/m/k. As another example, the top casing 825 can include a laminate comprising copper, polymer, and copper. With such a laminate casing, thermal vias through the polymer layer can be used to reduce thermal resistance. A cooling unit, e.g. liquid cooled cold plate, for example, can be attached to the inner copper layer through an opening of the polymer layer.

The bottom casing 830, for example, may include a single layer of material that has high thermal conductivity. The bottom casing 830, for example, may comprise copper, aluminum, stainless steel, silicon, ceramic, AlN, BeO, etc. The bottom casing 830, for example, may include a material that has a thermal conductivity greater than about 200 W/m/k. As another example, the bottom casing 830 can include a laminate comprising copper, polymer, and copper. With such a laminate casing, thermal vias through the polymer layer can be used to reduce thermal resistance. An electronic device, for example, can be attached to the inner copper layer through an opening of the polymer layer

An evaporation/boiling wick 805 and a condensation wick/may be disposed within the thermal ground plane 500. The evaporation/boiling wick 805 may be coupled or bonded with an inner surface of the bottom casing 830 and/or the condensation wick 810 may be coupled or bonded with an inner surface of the top casing 825. A plurality of support structures 815 may be disposed between the evaporation/boiling wick 805 and the condensation wick 810. The plurality of support structures 815, for example, may be bonded or in contact with the evaporation/boiling wick 805 and the condensation wick 810. The condensation wick 810 and/or the plurality of support structures 815 may include any or all the features or characteristics described in this document relative to the wick 120.

The condensation wick 810 may comprise a mesh with a pore size small enough to prevent vapor penetration into the condensation wick 810.

A plurality of liquid feed structures 820 may be disposed in certain portions (e.g., the heating regions) of the thermal ground plane 800 between the bottom casing 830 and top casing 825. The plurality of liquid feed structures 820 may be woven or mixed or combined with the plurality of support structures 815. The plurality of liquid feed structures 820 may comprise strips of a multilayer mesh. The plurality of liquid feed structures 820, for example, may be bonded or in contact with the evaporation/boiling wick 805 and the condensation wick 810. The plurality of liquid feed structures 820 may provide vertical and horizontal pathways for liquid to flow from the condensation wick 810 to the evaporation/boiling wick 805.

The plurality of liquid feed structures 820, for example, may comprise material substantially similar to the evaporation/boiling wick 805 and/or the condensation wick 810. The plurality of liquid feed structures 820, for example, may be bent out-of-plane compared with the evaporation/boiling wick 805.

As another example, the plurality of liquid feed structures 820 may include plurality of layers of mesh bonded together. The plurality of layers of mesh can be substantially similar to each other For example, three layers of mesh may be included with each layer having the same mesh number (e.g., #145). As another example, the plurality of layers of mesh may have different mesh numbers: a first mesh with a mesh number of #400 can be bonded to mesh with a mesh number of #200, which can be bonded to another mesh with a mesh number of #400. Small pores in the mesh (e.g., with a mesh number of #250, #300, or #400), for example, can prevent vapor penetration into the flow channel formed by the #200 mesh in liquid feed structure 820.

Portions of the vapor support structure 815 and portions of the plurality of liquid feed structures 820, for example, can be located within the same space or volume within the thermal ground plane.

The condensation wick 810 may be bonded with the top casing 825, for example, to maintain structure integrity under pressure difference between the vapor pressure inside the thermal ground plane and ambient pressure outside the thermal ground plane. The evaporation/boiling wick 805 may be bonded with the bottom casing 830, for example, to maintain structure integrity under pressure difference between the vapor pressure inside the thermal ground plane and ambient pressure outside the thermal ground plane. The plurality of support structures 815 may be bonded with condensation wick 810 and/or the evaporation/boiling wick 805, for example, to maintain structure integrity under pressure difference between the vapor pressure inside the thermal ground plane and ambient pressure outside the thermal ground plane.

FIG. 9A and FIG. 9B show different examples of the plurality of liquid feed structures 820 within a thermal ground plane. FIG. 9A shows a plurality of liquid feed structures 820 that extend through the condensation wick 810 to the top casing 825 and through the evaporation/boiling wick 805 to the bottom casing 830. In this example, the plurality of liquid feed structures 820 include out-of-plane bending in the shape of a triangular wave as shown. The triangular wave can be trapezoid wave in contact with the condensation wick 810 and the evaporation/boiling wick 805. FIG. 9B shows the plurality of liquid feed structures 820 that may have an asymmetric wave shape, which, for example, may allow for a higher area of contact to the condensation wick while limiting the area of contact with the evaporation/boiling wick.

The plurality of liquid feed structures 820 may be a porous wick or a multilayer mesh which allows liquid from the condensation wick 810 to travel to the evaporation/boiling wick 805 in the area of the heater. The capillary force associated with the liquid feed structure 820 may be sufficient to prevent a capillary limit associated with liquid in the boiling region. The liquid feed structure 820 may be in fluidic contact with both condensation wick 810 and evaporation/boiling wick 805, in order to allow liquid transport between them. The cross sectional area of the liquid feeding structure 820 in contact with the evaporation/boiling wick 805 is limited such that does not heat up to the point of boiling in the liquid feed structure 820. The liquid feed structure 820 is effective to transfer liquid vertically as well as horizontally. The horizontal transfer can be helpful to cover a large heating area with high heat fluxes.

The plurality of liquid feed structures 820 can be formed or cut to allow vapor to flow between liquid feed structures. The plurality of liquid feed structures 820 can be formed in a spiral, which may include cut-outs for vapor flow between segments of the spiral.

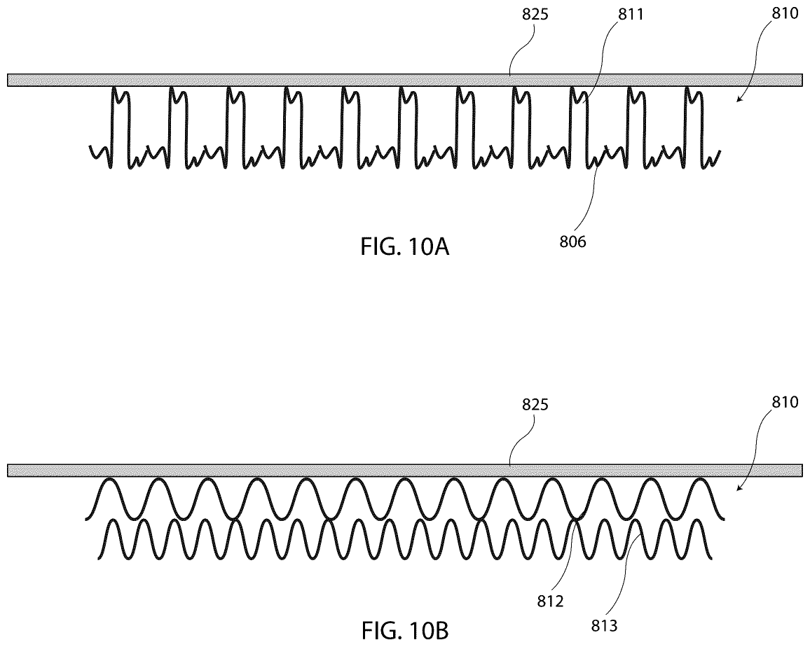

FIG. 10A and FIG. 10B illustrate two examples of condensation wick 810. The condensation wick 810 shown in FIG. 10A includes a mesh-on-pillars wick which includes a mesh layer 806 on a number of pillars 811. This wick can be a deformed mesh with mesh pillars. The pore size of the mesh in the condensation wick 810 may have a pore size less than 0.050 mm such as, for example, less than 0.010 mm, 0.025 mm, etc.

The condensation wick 810 shown in FIG. 10B shows a multiple layer mesh with each layer having different pore sizes. For example, the condensation wick 810 may include a first mesh 812, which is bonded with the top casing 825, and a second mesh 813. The first mesh 812 may be bonded with the second mesh 813. The first mesh 812 may have a larger pore size than the second mesh 813. For example, the first mesh 812 may be a mesh with a pore size corresponding to #100 and the second mesh 813 may be a mesh with a pore size corresponding to #200. The finer mesh (smaller pore size) may assure effective condensation, while the second mesh 813 may have a coarser mesh (larger pore size) coupled with the top casing 825 to provide an effective fluid channel for the condensed liquid flow. Such a multilayer mesh, for example, can provide effective condensation and liquid flow.

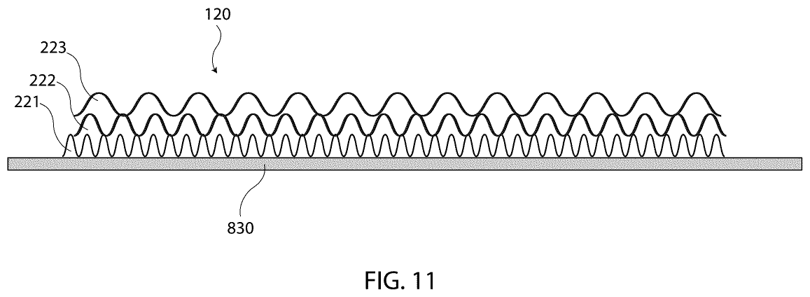

FIG. 11 illustrates an example of an evaporation/boiling wick 805 (or a wick 120 or a deformed wick 520). The evaporation/boiling wick 805 may be bonded to the bottom casing 830. The evaporation/boiling wick 805 may include a plurality of mesh layers. In this example, the evaporation/boiling wick 805 includes a first mesh 221, a second mesh 222, and a third mesh 223. In one example, the plurality of mesh layers may have different pore sizes. For example, the first mesh 221 may have a pore size of #400, the second mesh 222 may have a pore size of #200, and the third mesh 223 may have a pore size of #100. The mesh with the highest pore size may, for example, be bonded with the bottom casing 830. Such a multilayer mesh, for example, can provide effective evaporation and fluid flow. As another example, each of the plurality of mesh layers may have substantially similar pore sizes.

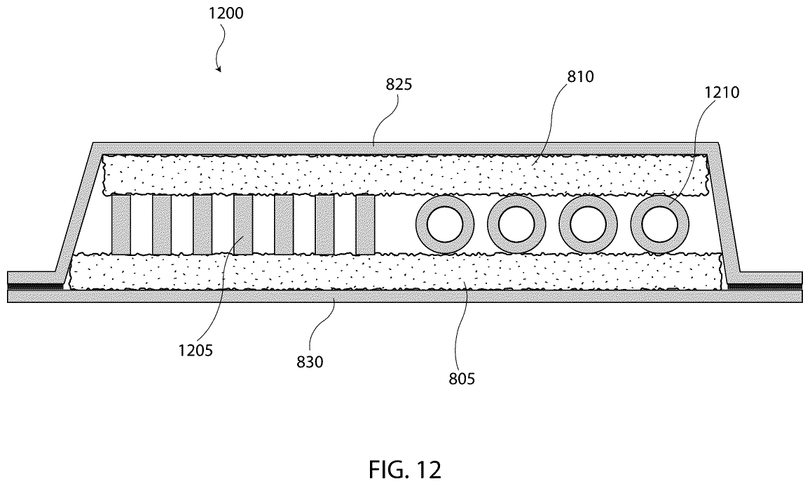

FIG. 12 is an illustration of a side view of a thermal ground plane 1200 that includes two types of vapor support structures hollow beads 1210 and/or solid pillars 1205 are disposed between the evaporation/boiling wick 805 and the condensation wick 810. Either or both may be used. The solid pillars 1205 and/or the hollow beads 1210 may be bonded with the evaporation/boiling wick 805 and/or the condensation wick 810, for example, to maintain structure integrity under pressure difference between the vapor pressure inside the thermal ground plane and ambient pressure outside the thermal ground plane.

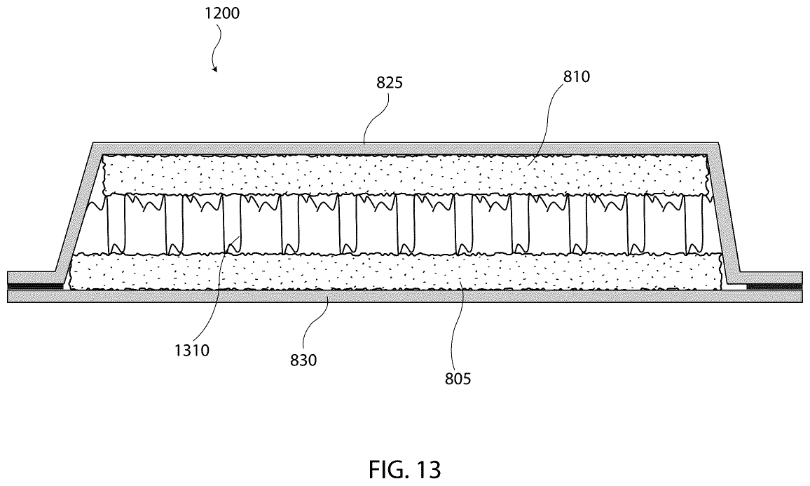

FIG. 13 is an illustration of a side view of a thermal ground plane 1200 that includes a deformed mesh 1310 as the vapor support structure/liquid feed structure disposed between condensation wick 810 and evaporation/boiling wick 805. In this example, the vapor support structure and the liquid feed structure are the same structure using deformed mesh 1310. The deformed mesh 1310, for example, may include a cut-out region near the heater. As another example, the deformed mesh 1310 can extend across the heater region and/or the liquid feed structure can be woven between the wires of the coarse mesh. The deformed mesh 1310 may be bonded with the boiling wick 805 and/or the 810, for example, to maintain structure integrity under pressure difference between the vapor pressure inside the thermal ground plane and ambient pressure outside the thermal ground plane. The deformed mesh 1310 may be a multilayer mesh.

The vapor support structure and liquid feed structure, for example, can be integrated with the casings as shown in FIG. 8A and/or can be deformable to accommodate different electronic device heights. For high heat flux applications, the electronic device must make effective thermal contacts with a thermal interface material between the electronic device and the thermal ground plane. The contact pressure level required is very high. Corresponding to such a high pressure level of each electronic device, there is an embodiment that deforms the casing/mesh locally. Such local deformations can accommodate different electronic device heights.

In some embodiments, the internal structures of the high heat flux thermal ground plane include micro-or nano-texturing. This texturing can be formed by oxidizing metal, by de-alloying brass into porous copper, by deposition of ceramic by atomic layer deposition, etc.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

While the present subject matter has been described in detail with respect to specific examples thereof, it will be appreciated that those skilled in the art, upon attaining an understanding of the foregoing, may readily produce alterations to, variations of, and equivalents to such examples. Accordingly, the present disclosure has been presented for purposes of example rather than limitation, and does not preclude inclusion of such modifications, variations and/or additions to the present subject matter as would be readily apparent to one of ordinary skill in the art.

That which is claimed:

1. A thermal ground plane comprising:
a first casing that is substantially planar;
a second casing, wherein the outer periphery of the first casing and the outer periphery of the second casing are bonded to each other to form a hermetic seal, wherein the second casing is deformed to create a vapor support structure that includes a plurality of deformed portions;
a working fluid disposed within the first casing and the second casing;
a permeable wick disposed on an inner surface of the first casing for liquid transport disposed between the first casing and the second casing.

2. The thermal ground plane according to claim 1, wherein second casing comprises at least one of copper, aluminum, and stainless steel.

3. The thermal ground plane according to claim 1, wherein second casing comprises a flexible laminate having a plurality of layers where at least one of the plurality of layers comprises polymer.

4. The thermal ground plane according to claim 1, wherein second casing has a thickness less than 0.036 mm.

5. The thermal ground plane according to claim 1, wherein the permeable wick is bonded with both the first casing and portions of the second casing.

6. The thermal ground plane according to claim 1, further comprising a second wick disposed on an inner surface of the second casing.

7. The thermal ground plane according to claim 6, wherein portions of the second wick are bonded to the second casing and some portions of the second wick are bonded with the permeable wick and wherein the permeable wick is bonded to the first casing.

8. The thermal ground plane according to claim 1, wherein the permeable wick is flattened and deformed to form a plurality of deformations for liquid transport.

9. The thermal ground plane according to claim 1, wherein the thermal ground plane comprises a plurality of flexures that are configured to connect with a substrate and allow relative movement of portions of the thermal ground plane.

10. A thermal ground plane comprising:
a first casing;
a first wick bonded with the first casing, the first wick for liquid transport associated with evaporation or boiling;
a second casing, wherein the outer periphery of the first casing and the outer periphery of the second casing are bonded to each other to form a hermetic seal;
a second wick bonded with the second casing, the second wick for liquid transport associated with condensation;
a liquid feed structure in contact with the first wick and the second wick for liquid transport, the liquid feed structure having a structure configured to allow vertical liquid transport between the first wick and the second wick and horizontal liquid transport along the liquid feed structure; and
a working fluid disposed within the first casing and the second casing.

11. The thermal ground plane according to claim 10, wherein the liquid feed structure comprises a mesh selected from the group consisting of copper mesh, stainless steel mesh, and polymer mesh.

12. The thermal ground plane according to claim 10, wherein the liquid feed structure comprises a plurality of mesh layers.

13. The thermal ground plane according to claim 12, wherein at least one of the plurality of mesh layers comprises a mesh number of #300 or greater.

14. The thermal ground plane according to claim 10, wherein the liquid feed structure has a shape selected from the group consisting of a wavy shape, a triangular shape, a trapezoid shape, and an asymmetric wave shape.

15. The thermal ground plane according to claim 10, further comprising a vapor support structure disposed between the first casing and the second casing.

16. The thermal ground plane according to claim 15, wherein the vapor support structure and the liquid feed structure are disposed in the same space within the thermal ground plane.

17. The thermal ground plane according to claim 10, wherein the second wick comprises a plurality of mesh layers.

18. The thermal ground plane according to claim 17, wherein the plurality of mesh layers comprises at least a first mesh layer and a second mesh layer, the first mesh layer has a pore size greater than the pore size of the second mesh layer, and the first mesh layer is disposed between the second casing and the second mesh layer.

19. The thermal ground plane according to claim 10, wherein the first wick comprises a plurality of mesh layers.

20. The thermal ground plane according to claim 19, wherein the plurality of mesh layers comprises at least a first mesh layer and a second mesh layer, the first mesh layer has a pore size greater than the pore size of the second mesh layer, and the second mesh layer is disposed between the first casing and the first mesh layer.
